(19) United States
(12) Patent Application Publication
(10) Pub. No.: US 2016/0212861 A1
(43) Pub. Date: Jul. 21, 2016

(54) METHOD FOR FABRICATING SENSING DEVICE

(71) Applicant: Primax Electronics Ltd., Neihu (TW)

(72) Inventors: CHIA-CHU CHENG, Neihu (TW); CHIH-CHUANG CHU, Neihu (TW)

(21) Appl. No.: 14/665,240

(22) Filed: Mar. 23, 2015

(30) Foreign Application Priority Data
Jan. 19, 2015 (TW) 104101690

(51) Int. Cl. H05K 3/28; H05K 3/36; G06K 9/00; H05K 3/30

(52) U.S. Cl. CPC H05K 3/284; H05K 3/305; H05K 3/361; G06K 9/0002

(57) ABSTRACT

A method for fabricating a sensing device includes the following steps. Firstly, an adhering process is performed to attach a sensing integrated circuit on a first circuit board, wherein the sensing integrated circuit has a sensing surface. Then, a packaging process is performed to encapsulate the first circuit board within a package shell, so that at least a portion of a top surface of the first circuit board is covered by the package shell. The sensing surface of the sensing integrated circuit is exposed to a top surface of the package shell. Afterwards, a protective layer is attached on the sensing surface.

### FIELD OF THE INVENTION

The present invention relates to a method for fabricating a sensing device, and more particularly to a method for fabricating a fingerprint sensing device.

### BACKGROUND OF THE INVENTION

Nowadays, a fingerprint sensing device is gradually applied to a portable electronic device. The principles of the fingerprint sensing device will be described as follows. A sensing electrode layer is integrated into a chip. When a surface of the chip is pressed by a user's finger, the ridges and the valleys of a user's finger generate different capacitance values on the sensing electrode layer, and the fingerprint image of the user's finger is acquired by the chip according to the capacitance values.

The structure of a conventional fingerprint sensing device 1 is shown in FIG. 1. The method of fabricating the conventional fingerprint sensing device 1 will be illustrated as follows. Firstly, a circuit board 11 is provided. Then, a sensing chip 12 is installed on a top surface of the circuit board 11. Then, a protective layer 13 is provided to cover the sensing chip 12. Due to the protective layer 13, the user's finger is not in directly contact with the surface of the sensing chip 12. In other words, the arrangement of the protective layer 13 can protect the sensing chip 12 from being over-pressed, scratched and damaged or avoid the sweat erosion and other problems.

Since the protective layer 13 is finally exposed to the surface of the electronic device to be pressed by the user's finger, the size and the shape of the protective layer 13 are determined according to the final product of the electronic device. For example, the size of the protective layer 13 may be larger than or smaller than the sensing chip 12, and the shape of the protective layer 13 may be a circular shape or a square shape. If the size of the protective layer 13 is larger than the sensing chip 12, there is a gap distance X between the protective layer 13 and the circuit board 11 (see FIG. 1). Under this circumstance, the protective layer 13 is suspended, and thus the protective layer 13 is easily crushed by the user's finger. For solving this drawback, it is necessary to install an additional component around the sensing chip 12 during the fabricating process. That is, the additional component is disposed under the suspended region of the protective layer 13. Moreover, for complying with the different shape of the protective layer 13, it is possible to install more components to support the protective layer 13.

Moreover, it is necessary to install other insulating layer or protective layer on the bottom surface of the circuit board to protect the circuit board 11. In other words, the method of fabricating the conventional fingerprint sensing device 1 is very complicated.

Therefore, there is a need of providing a method for fabricating a sensing device with a reduced process complexity.

### SUMMARY OF THE INVENTION

An object of the present invention provides a method for fabricating a sensing device with a reduced process complexity.

In accordance with an aspect of the present invention, there is provided a method for fabricating a sensing device. Firstly, an adhering process is performed to attach a sensing integrated circuit on a first circuit board, wherein the sensing integrated circuit has a sensing surface. Then, a packaging process is performed to encapsulate the first circuit board within a package shell, so that at least a portion of a top surface of the first circuit board is covered by the package shell. The sensing surface of the sensing integrated circuit is exposed to a top surface of the package shell. Afterwards, a protective layer is attached on the sensing surface.

The above objects and advantages of the present invention will become more readily apparent to those ordinarily skilled in the art after reviewing the following detailed description and accompanying drawings, in which:

### BRIEF DESCRIPTION OF THE DRAWINGS

FIG. 1 schematically illustrates the structure of a conventional fingerprint sensing device;

FIG. 2 is a flowchart illustrating a method for fabricating a sensing device according to an embodiment of the present invention;

FIG. 3 is a perspective view illustrating a circuit board assembly of a sensing device according to an embodiment of the present invention;

FIG. 4 is a schematic perspective view illustrating a semi-finished product of the sensing device before being packaged;

FIG. 5 is a schematic perspective view illustrating the semi-finished product of the sensing device of FIG. 4 and taken along another viewpoint;

FIG. 6 schematically illustrates a mold assembly used in the packaging process of the sensing device according to an embodiment of the present invention;

FIG. 7 schematically a semi-finished product of the sensing device placed within the mold assembly before being packaged;

FIG. 8 is a schematic top view illustrating the semi-finished product of the sensing device after being packaged;

FIG. 9 is a schematic rear view illustrating the semi-finished product of the sensing device after being packaged;

FIG. 10 is a schematic perspective view illustrating the sensing device with the protective layer according to an embodiment of the present invention; and

FIG. 11 schematically illustrates the sensing device of the present invention in a usage state, in which a user's finger is placed on the protective layer.

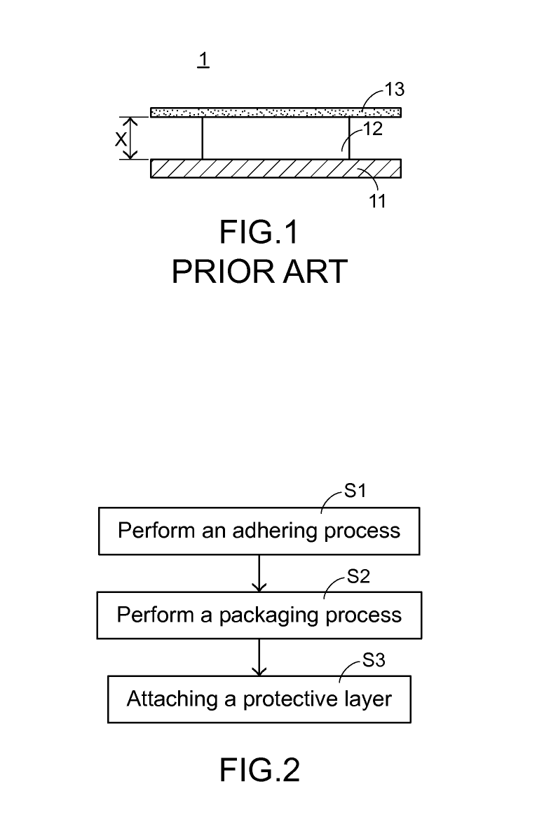

### DETAILED DESCRIPTION OF THE PREFERRED EMBODIMENT

The present invention provides a method for fabricating a sensing device. As shown in FIG. 2, the fabricating method comprises the following steps. In a step S1, an adhering process is performed. In a step S2, a packaging process is performed. In a step S3, a protective layer is attached on a sensing surface. These steps will be illustrated in more details as follows.

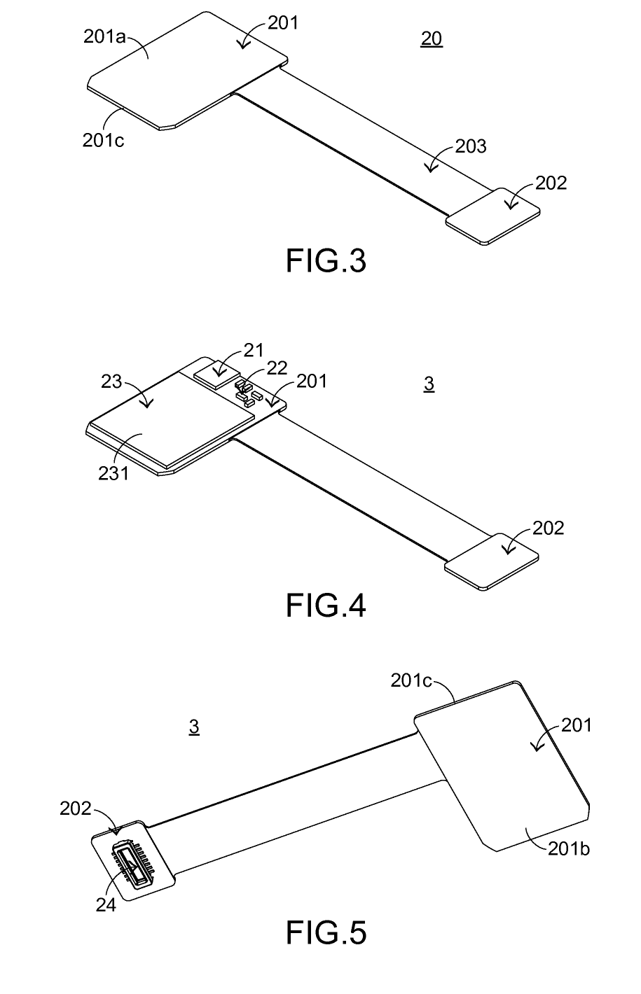

FIG. 3 is a perspective view illustrating a circuit board assembly of a sensing device according to an embodiment of the present invention. The circuit board assembly 20 is provided for performing the subsequent steps (i.e. the adhering process S1, the packaging process S2 and the protective layer attaching process S3). In this embodiment, the circuit board assembly 20 is a rigid-flex board assembly. The circuit board assembly 20 comprises a first circuit board 201, a second circuit board 202 and a flexible printed circuit board (FPCB) 203. The first circuit board 201 and the second circuit board 202 are rigid printed circuit boards. Moreover, the first circuit board 201 and the second circuit board 202 are electrically connected with each other through the flexible printed circuit board 203. The use of the rigid-flex board assembly as the circuit board assembly 20 is presented herein for purpose of illustration and description only. It is noted that numerous modifications and alterations may be made while retaining the teachings of the invention. Preferably but not exclusively, in a variant example, only the first circuit board 201 is provided as a substrate, and the first circuit board 201 is a rigid printed circuit board or a flexible printed circuit board.

Hereinafter, the adhering process S1 will be illustrated with reference to FIGS. 4 and 5. FIG. 4 is a schematic perspective view illustrating a semi-finished product of the sensing device before being packaged. FIG. 5 is a schematic perspective view illustrating the semi-finished product of the sensing device of FIG. 4 and taken along another viewpoint. In the adhering process, a signal processing integrated circuit 21, an electronic component 22 and a sensing integrated circuit 23 are attached on a top surface 201a of the first circuit board 201, and a connector 24 is attached on the second circuit board 202. Consequently, a semi-finished product 3 of the sensing device before being packaged is produced. The sequence of attaching the signal processing integrated circuit 21, the electronic component 22 and the sensing integrated circuit 23 and the position of the connector 24 may be altered according to the practical requirements.

In this embodiment, the adhering process S1 is a surface mount technology (SMT) process. That is, solder paste is firstly printed on the first circuit board 201 and the second circuit board 202. Then, the signal processing integrated circuit 21, at least one electronic component 22 and the sensing integrated circuit 23 are placed on corresponding locations of the first circuit board 201 with the solder paste, and the connector 24 is placed on the corresponding location of the second circuit board 202 with the solder paste. Then, the first circuit board 201 and the second circuit board 202 are passed through a reflow furnace (not shown). Consequently, the molten solder paste surrounds the pins of the signal processing integrated circuit 21, the electronic component 22, the sensing integrated circuit 23 and the connector 24. Meanwhile, the signal processing integrated circuit 21, the electronic component 22 and the sensing integrated circuit 23 are welded on the first circuit board 201, and the connector 24 is welded on the second circuit board 202. It is noted that the adhering process S1 is not restricted.

Moreover, an example of the electronic component 22 includes but is not limited to a resistor, a capacitor, an electrostatic discharge (ESD) protection component or any other appropriate electronic component. The number and positions of the at least one electronic component 22 are not restricted to those shown in the drawings.

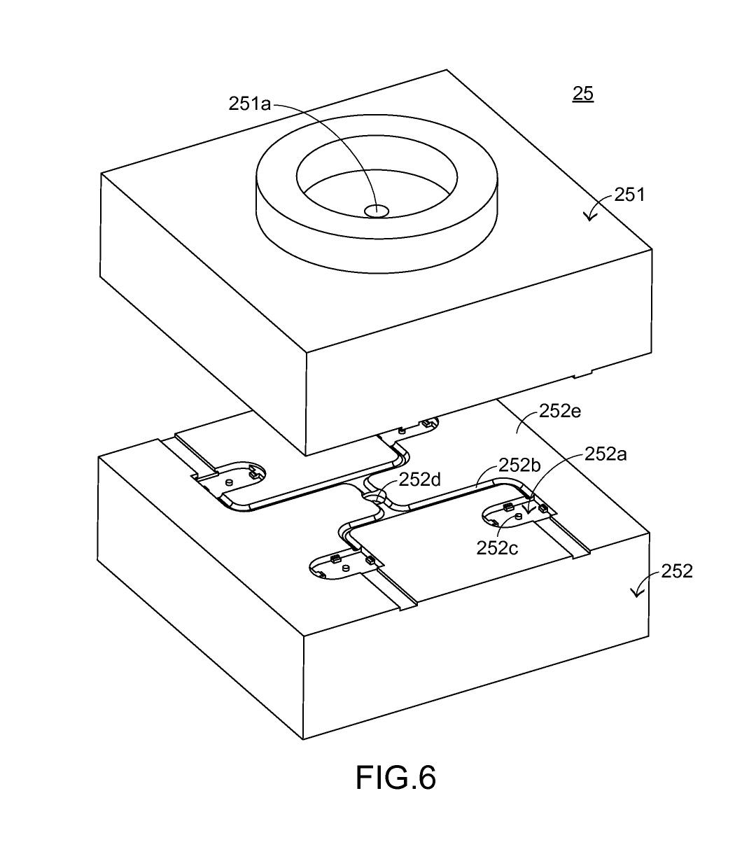

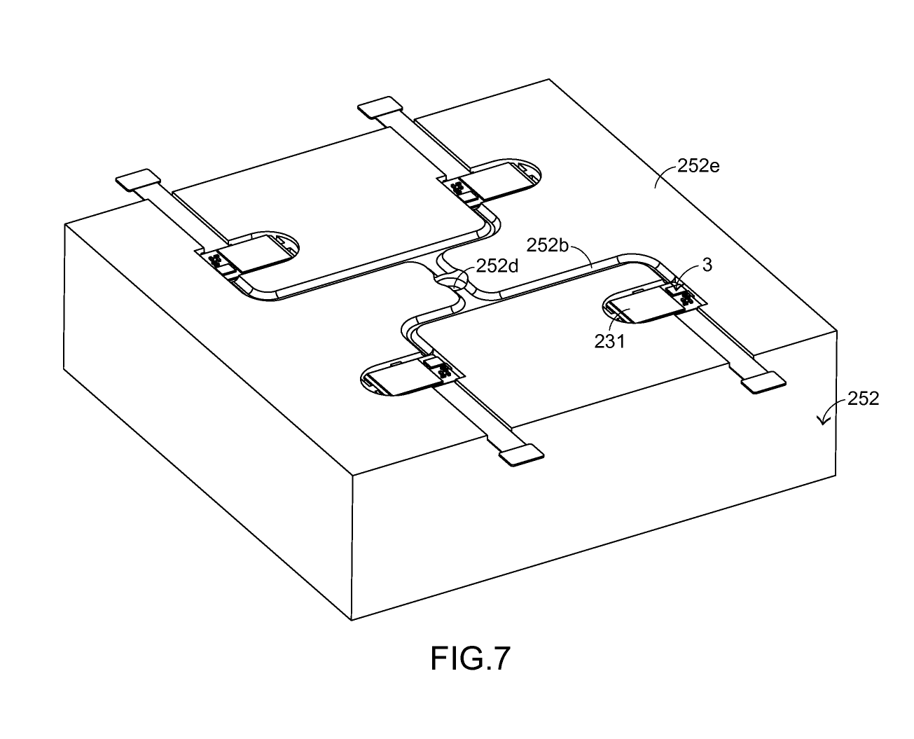

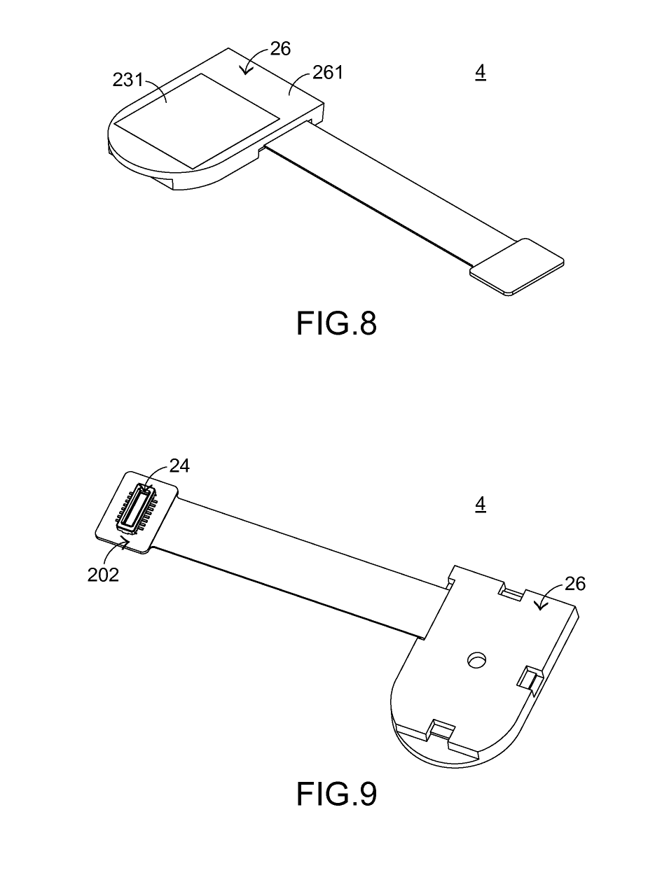

Hereinafter, the packaging process S2 will be illustrated with reference to FIGS. 6, 7, 8 and 9. FIG. 6 schematically illustrates a mold assembly used in the packaging process of the sensing device according to an embodiment of the present invention. FIG. 7 schematically a semi-finished product of the sensing device placed within the mold assembly before being packaged. FIG. 8 is a schematic top view illustrating the semi-finished product of the sensing device after being packaged. FIG. 9 is a schematic rear view illustrating the semi-finished product of the sensing device after being packaged.

As shown in FIG. 6, the mold assembly 25 comprises an upper half mold 251 and a lower half mold 252. The upper half mold 251 comprises a perforation 251a. The lower half mold 252 comprises plural receiving recesses 252a and plural grooves 252b. The plural grooves 252b are in communication with the plural receiving recesses 252a. The length and the width of the receiving recess 252a are larger than the length and the width of the first circuit board 201. Moreover, plural bulges 252c are formed in each receiving recess 252a. It is noted that the numbers of the receiving recesses 252a and the bulges 252c are not restricted. For clarification and brevity, only four receiving recesses 252a are shown in FIG. 6, wherein four bulges 252c are formed in each receiving recess 252a. However, the lower half mold 252 comprising a single receiving recess 252a or plural receiving recesses 252a and the receiving recess 252a comprising a single bulge 252c or plural bulges 252c are included within the scope of the present invention. That is, the structures of the upper half mold 251 and the lower half mold 252 and not restricted to those shown in FIG. 6.

Please refer to FIG. 7. During the packaging process, the semi-finished product 3 of the sensing device before being packaged is accommodated within the corresponding receiving recess 252a. Under this circumstance, the signal processing integrated circuit 21, and the electronic component 22 and the sensing integrated circuit 23 face upwardly. Moreover, since the first circuit board 201 is raised by the plural bulges 252c, a bottom surface 201b of the first circuit board 201 is suspended.

Then, the upper half mold 251 and the lower half mold 252 are combined together. Consequently, the perforation 251a of the upper half mold 251 and a junction zone 252d of the plural grooves 252b are in communication with each other. After an encapsulating material (e.g. epoxy resin) is fed into the perforation 251a, the encapsulating material is introduced into the plural receiving recesses 252a through the plural grooves 252b. Since there is a height difference between a top surface 252e of the lower half mold 252 and the top surface 201a of the first circuit board 201, the encapsulating material can be introduced into the space between the top surface 201a of the first circuit board 201 and the corresponding receiving recess 252a. Moreover, since the length and the width of the receiving recess 252a are larger than the length and the width of the first circuit board 20, the encapsulating material can be introduced into the space between a lateral surface 201c of the first circuit board 201 and the corresponding receiving recess 252a. Moreover, since the first circuit board 201 is raised by the plural bulges 252c and the bottom surface 201b of the first circuit board 201 is suspended, the encapsulating material can be introduced into the space between the bottom surface 201b of the first circuit board 201 and the corresponding receiving recess 252a. Please refer to the top view of FIG. 8 and the rear view of FIG. 9. After the packaging process is completed, the package shell 26 encapsulating the first circuit board 21 is integrally formed, and the semi-finished product 4 of the sensing device after being packaged is produced.

In the packaging process S2, the temperature of the encapsulating material is lower than a tolerable temperature that causes damage to the shape or the performance of the first circuit board 201 and any component of the first circuit board 201. For example, the temperature of the encapsulating material is lower than a melting temperature of the solder paste. Moreover, while the encapsulating material is fed into mold assembly 25, the pressure of the encapsulating material is lower than the tolerable pressure that causes damage to the shape, the performance or the adhesion of the first circuit board 201 and any component of the first circuit board 201.

In this embodiment, the sensing integrated circuit 23 is thicker than other components of the first circuit board 201. Moreover, as shown in FIG. 7, there is no height difference between the sensing surface 231 of the sensing integrated circuit 23 and the top surface 252e of the lower half mold 252. Moreover, the amount of the encapsulating material is elaborately calculated so as to be filled into the receiving recess 252a only. Consequently, the encapsulating material covers the top surface 201a of the first circuit board 201 (including the signal processing integrated circuit 21 and the electronic component 22), but does not cover the sensing surface 231 of the sensing integrated circuit 23. Since the sensing surface 231 of the sensing integrated circuit 23 is not covered by the encapsulating material, the sensing surface 231 of the sensing integrated circuit 23 is exposed to a top surface 261 of the package shell 26. Moreover, the sensing surface 231 of the sensing integrated circuit 23 and the top surface 261 of the package shell 26 are in the same plane. That is, as shown in FIG. 8, there is no height difference between the sensing surface 231 of the sensing integrated circuit 23 and the top surface 261 of the package shell 26. Moreover, for preventing the sensing surface 231 of the sensing integrated circuit 23 from being covered by the encapsulating material, the design may be modified. For example, in another embodiment, after the upper half mold 251 and the lower half mold 252 are combined together, the sensing surface 231 of the sensing integrated circuit 23 is in contact with the upper half mold 251. Since there is no gap between the sensing surface 231 of the sensing integrated circuit 23 and the upper half mold 251, the encapsulating material cannot flow therethrough.

The package shell 26 of the above embodiment is presented herein for purpose of illustration and description only. It is noted that numerous modifications and alterations may be made while retaining the teachings of the present invention. For example, in another embodiment, only a portion of the top surface 201a of the first circuit board 201, a portion of the bottom surface 201b of the first circuit board 201 and a portion of the lateral side surface 201c are covered by the package shell 26. Alternatively, in another embodiment, the entire or a portion of the top surface 201a of the first circuit board 201 and the entire or a portion of the bottom surface 201b of the first circuit board 201 are covered by the package shell 26.

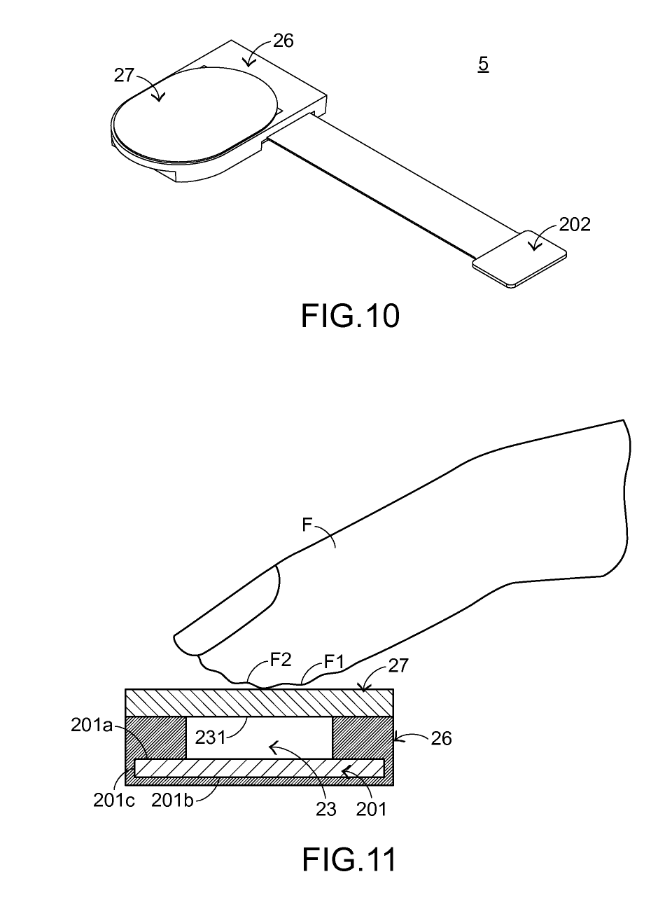

FIG. 10 is a schematic perspective view illustrating the sensing device with the protective layer according to an embodiment of the present invention. For protecting the sensing surface 231 of the sensing integrated circuit 23 from being over-pressed, scratched and damaged or avoiding the sweat erosion and other problems, a protective layer 27 is attached on the sensing surface 231 after the above processes. Consequently, the finished product 5 of the sensing device of the present invention is produced. In an embodiment, the protective layer 27 is made of isotropic dielectric material or anisotropic dielectric material with high dielectric constant. An example of the isotropic dielectric material or the anisotropic dielectric material with high dielectric constant includes but is not limited to zirconium dioxide or sapphire crystal glass. Preferably but not exclusively, the protective layer 27 is attached on the sensing surface 231 through an adhesive or a double side tape.

As mentioned above, the sensing surface 231 of the sensing integrated circuit 23 and the top surface 261 of the package shell 26 are in the same plane. That is, there is no height difference between the sensing surface 231 of the sensing integrated circuit 23 and the top surface 261 of the package shell 26. Consequently, if the size of the protective layer 27 is larger than the sensing surface 231 of the sensing integrated circuit 23, the protective layer 27 may be directly attached on the plane. Moreover, since the protective layer 27 is supported by the top surface 261 of the package shell 26, the protective layer 27 is not suspended. Under this circumstance, it is not necessary to install other components around the sensing integrated circuit 23 to support the protective layer 27.

Hereinafter, the operating principles of the sensing device will be illustrated with reference to FIG. 11. FIG. 11 schematically illustrates the sensing device of the present invention in a usage state, in which a user's finger is placed on the protective layer. Firstly, the sensing surface 231 of the sensing integrated circuit 23 is defined as an electrode layer. Generally, the human body is an electric conductor. Consequently, when a user's finger F is placed on the protective layer 27, the user's finger F may be considered as another electrode layer. Meanwhile, a capacitive coupling effect occurs between the user's finger F and the sensing surface 231 of the sensing integrated circuit 23. Since the surface of the user's finger F comprises plural ridges F1 and plural valleys F2, the distances of each point on the surface of the user's finger F from the sensing surface 231 of the sensing integrated circuit 23 are not completely identical. That is, the intensities of the electric signals sensed by the sensing integrated circuit 23 are not completely identical. Consequently, the sensing integrated circuit 23 can realize the distances between the sensing surface 231 and all points of the user's finger F. According to these distances, the fingerprint image information corresponding to the surface of the user's finger F including the plural ridges F1 and the plural valleys F2 can be obtained.

Alternatively, in another embodiment, different intensities of plural electric signals are acquired by the sensing integrated circuit 23 according to the capacitive coupling effect between the sensing integrated circuit 23 and plural ridges F1 and plural valleys F2 of the user's finger F, and the fingerprint image information corresponding to the surface of the user's finger F is obtained by the signal processing integrated circuit 21 according to the plural electric signals. In case that the fingerprint image information corresponding to the surface of the user's finger F is obtained by the sensing integrated circuit 23, the signal processing integrated circuit 21 may be omitted.

From the above descriptions, the present invention provides the method for fabricating the sensing device. After the packaging process is performed, the package shell 26 encapsulating the top surface 201a, the bottom surface 201b and the lateral side surface 201c of the first circuit board 21 is integrally formed. Moreover, by the specially designed mold assembly, the sensing surface 231 of the sensing integrated circuit 23 is exposed to the top surface 261 of the package shell 26, and the sensing surface 231 of the sensing integrated circuit 23 and the top surface 261 of the package shell 26 are coplanar with each other (i.e. without height difference). Consequently, regardless of whether the size of the protective layer 27 is larger than the sensing integrated circuit 23, the protective layer 27 can be directly attached on the top surface package shell 26. Under this circumstance, it is not necessary to install other components on the peripheries of the sensing integrated circuit 23 to support the protective layer 27. Moreover, since the bottom surface 201b of the first circuit board 21 is also encapsulated by the package shell 26, it is not necessary to install other insulating layer or protective layer on the bottom surface 201b of the first circuit board 21 to protect the first circuit board 21. Accordingly, the fabricating method of the present invention is capable of reducing the process complexity.

While the invention has been described in terms of what is presently considered to be the most practical and preferred embodiments, it is to be understood that the invention needs not be limited to the disclosed embodiments. On the contrary, it is intended to cover various modifications and similar arrangements included within the spirit and scope of the appended claims which are to be accorded with the broadest interpretation so as to encompass all such modifications and similar structures.

What is claimed is:

1. A method for fabricating a sensing device, the method comprising steps of:
performing an adhering process of attaching a sensing integrated circuit on a first circuit board, wherein the sensing integrated circuit has a sensing surface;
performing a packaging process of encapsulating the first circuit board within a package shell, so that at least a portion of a top surface of the first circuit board is covered by the package shell, wherein the sensing surface of the sensing integrated circuit is exposed to a top surface of the package shell; and
attaching a protective layer on the sensing surface.

2. The method according to claim 1, wherein the sensing surface of the sensing integrated circuit and the top surface of the package shell are in the same plane, wherein the protective layer is attached on the plane, and the sensing surface of the sensing integrated circuit is at least covered by the protective layer.

3. The method according to claim 1, wherein the packaging process comprises steps of:
placing the first circuit board in one of at least one receiving recess of a mold assembly; and
filling an encapsulating material into the receiving recess, so that the package shell encapsulating the first circuit board is formed.

4. The method according to claim 3, wherein a temperature of the encapsulating material is lower than a tolerable temperature which causes damage to the first circuit board and a component of the first circuit board.

5. The method according to claim 3, wherein the mold assembly comprises:
an upper half mold having a perforation, wherein the encapsulating material is fed into the perforation: and
a lower half mold comprising the at least one receiving recess and a groove, wherein the groove is in communication with the at least one receiving recess,
wherein when the upper half mold and the lower half mold are combined together, the perforation and the groove are in communication with each other, so that the encapsulating material is introduced into the receiving recess through the groove.

6. The method according to claim 3, wherein while the encapsulating material is fed into mold assembly, a pressure of the encapsulating material is lower than a tolerable pressure which causes damage to the first circuit board and a component of the first circuit board.

7. The method according to claim 5, wherein there is a height difference between a top surface of the lower half mold and the top surface of the first circuit board, so that the encapsulating material is permitted to be introduced into a space between the top surface of the first circuit board and the corresponding receiving recess.

8. The method according to claim 3, wherein at least one bulge is formed in the receiving recess, and the first circuit board is raised by the bulge, so that a bottom surface of the first circuit board is suspended and the encapsulating material is permitted to be introduced into a space between the bottom surface of the first circuit board and the corresponding receiving recess.

9. The method according to claim 3, wherein a length and a width of the receiving recess are larger than those of the first circuit board, so that the encapsulating material is permitted to be introduced into a space between a lateral surface of the first circuit board and the corresponding receiving recess.

10. The method according to claim 3, wherein the encapsulating material is made of epoxy resin.

11. The method according to claim 1, wherein the sensing integrated circuit acquires plural electric signals with different intensities according to a capacitive coupling effect between the sensing integrated circuit and ridges and valleys on a surface of a user's finger, and the sensing integrated circuit acquires a fingerprint image information corresponding to the user's finger according to the electric signals.

12. The method according to claim 1, wherein the adhering process further comprises a step of attaching a signal processing integrated circuit on the first circuit board.

13. The method according to claim 12, wherein the sensing integrated circuit acquires plural electric signals with different intensities according to a capacitive coupling effect between the sensing integrated circuit and ridges and valleys on a surface of a user's finger, and the signal processing integrated circuit acquires a fingerprint image information corresponding to the user's finger according to the electric signals.

14. The method according to claim 12, wherein the sensing integrated circuit is thicker than the signal processing integrated circuit, wherein during the packaging process, the signal processing integrated circuit is encapsulated within the package shell.

15. The method according to claim 1, wherein the adhering process further comprises a step of attaching an at least one electronic component on the first circuit board.

16. The method according to claim 15, wherein the electronic component is a resistor, a capacitor or an electrostatic discharge (ESD) protection component.

17. The method according to claim 15, wherein the sensing integrated circuit is thicker than the at least one electronic component, wherein during the packaging process, the at least one electronic component is encapsulated within the package shell.

18. The method according to claim 1, wherein the adhering process further comprises a step of attaching a connector on a second circuit board.

19. The method according to claim 18, wherein the first circuit board and the second circuit board are rigid printed circuit boards, and the first circuit board and the second circuit board are connected with each other through a flexible printed circuit board.

20. The method according to claim 19, wherein the first circuit board, the second circuit board and the flexible printed circuit board are combined as a rigid-flex board assembly.

21. The method according to claim 1, wherein the adhering process is a surface mount technology (SMT) process.

22. The method according to claim 1, wherein the protective layer is made of zirconium dioxide or sapphire crystal glass.
